(19) United States
(12) Patent Application Publication
(10) Pub. No.: US 2025/0232992 A1
(43) Pub. Date: Jul. 17, 2025

(54) DEPOSITION APPARATUS WITH DETECTION SYSTEM AND METHODS

(71) Applicant: Taiwan Semiconductor Manufacturing Company Ltd., Hsinchu (TW)

(72) Inventors: Ming-Yao HSIAO, Hsinchu (TW); Yu-Sen CHU, Hsinchu (TW)

(21) Appl. No.: 18/412,209

(22) Filed: Jan. 12, 2024

(51) Int. Cl. H01L 21/67; C23C 16/40; C23C 16/44; C23C 16/52; G01N 15/075; H01L 21/02; H01L 21/66

(52) U.S. Cl. CPC H01L 21/67253; C23C 16/402; C23C 16/4408; C23C 16/4412; C23C 16/52; G01N 15/075; H01L 21/0217; H01L 21/02211; H01L 22/20

(57) ABSTRACT

A method includes: flowing a process gas into a chamber of a furnace; forming a material layer on a wafer via the process gas; flowing a purge gas into the chamber; exhausting the purge gas and particles from the chamber via an exhaust line; detecting the particles in the exhaust line; determining whether a particle parameter associated with the particles exceeds a threshold value; and in response to the particle parameter exceeding the threshold value, adjusting flow of the purge gas into the chamber.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs. For example, data centers including large numbers of servers support planning and manufacturing of the ICs. Individual servers may be cooled by passive cooling, air cooling, water cooling or immersion cooling. None of these cooling methods has been entirely sufficient for various reasons.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrammatic views of a furnace with cleaning system according to embodiments of the present disclosure.

FIG. 2 is a schematic view of a controller according to various aspects of the present disclosure.

FIGS. 3A, 3B and 4 are diagrammatic views of detection systems according to various aspects of the present disclosure.

FIGS. 5 and 6 are flowcharts of methods of cleaning a furnace in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms such as “about,” “roughly,” “substantially,” and the like may be used herein for ease of description. A person having ordinary skill in the art will be able to understand and derive meanings for such terms.

Semiconductor fabrication generally involves the formation of electronic circuits by performing multiple depositions, etchings, annealings, and/or implantations of material layers, whereby a stack structure including many semiconductor devices and interconnects between is formed. Some deposition operations are performed by a chemical vapor deposition (CVD) apparatus that includes a furnace. For example, a high-temperature oxide (HTO) thin film may be formed in the furnace of the CVD apparatus.

A chemical reaction for forming the HTO thin film may be SiH2Cl2+2 N2O->SiO2+2 N2+2 HCl. Generally, gas inlets that introduce process gases cannot be rotated and the process frequently encounters an incomplete reaction. Due to the incomplete reaction, particles may be produced, which may settle on surfaces of a wafer on which the HTO thin film is formed as well as on structures within a chamber of the furnace. These particles that settle on the wafer result in defects, which decreases yield. While some particles may be removed by a purge gas, such as N2, the purge gas flow may not be sufficient to remove all of the particles.

In embodiments of the disclosure, an optical scanner or detector is positioned adjacent an exhaust line. The optical scanner detects amount of particles within an exhaust gas that flows through the exhaust line. Based on the amount of particles detected exceeding a threshold value, a controller may increase flow of the purge gas to improve removal of the particles in the chamber of the furnace.

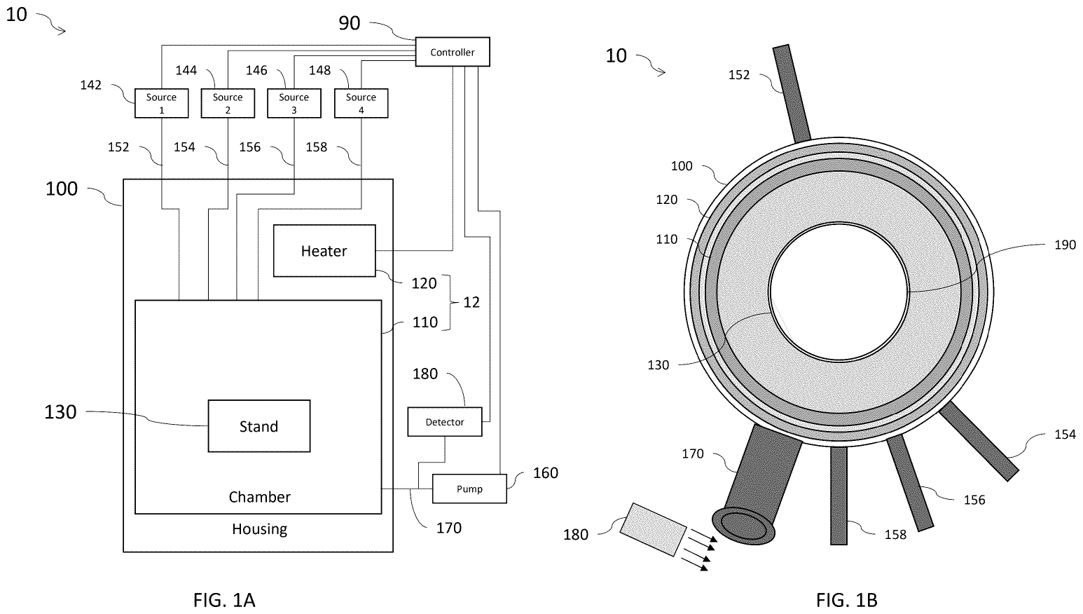

FIGS. 1A and 1B are diagrammatic views of a CVD apparatus having a furnace including an optical scanner according to embodiments of the present disclosure. The views of FIGS. 1A and 1B are simplified, and one or more elements may be omitted from view for clarity of illustration.

A chemical vapor deposition (CVD) apparatus 10 includes a housing 100, a chamber 110 within the housing 100, a wafer stand or stage 130 inside the chamber 110, a heater 120 adjacent the chamber 110, gas transport lines 152, 154, 156, 158 coupled to gas sources or supplies 142, 144, 146, 148, respectively, an exhaust line 170, a detector 180 adjacent the exhaust line 170, a pump 160 coupled to the exhaust line 170 and a controller 90 in data communication with the heater 120, gas sources 142, 144, 146, 148, pump 160 and detector 180. In some embodiments, the CVD apparatus 10 is a low-pressure CVD (LPCVD) apparatus. The CVD apparatus 10 may be referred to as the apparatus 10. The combination of the chamber 110 and the heater 120 may be referred to collectively as a furnace 12. One or more elements of the apparatus 10 may be omitted from view for simplicity. For example, the apparatus 10 may include a wafer boat and/or wafer loading system, a cooling system, temperature and/or pressure sensors, safety systems, and the like.

The housing 100 may form an external structure or casing of the furnace 12. The housing 100 provides a barrier between internal components and an external environment, such that conditions inside the furnace 12 are isolated and controlled. The housing 100 may include a material selected to be beneficial for handling thermal, chemical, and mechanical stresses associated with operation of the furnace 12. The housing 100 may include materials such as stainless steel or other alloys that have improved durability and resistance to corrosion. The housing 100 may include an insulation layer beneficial to prevent heat loss from the furnace 12, which improves retention of the high temperatures used in oxide growth while protecting the external environment from excess heat. The housing 100 may support physically various subsystems, such as the chamber 110, heater 120, cooling system, gas delivery (e.g., the gas transport lines 152, 154, 156, 158) and control systems. The housing 100 provides a framework to hold these components in place and allows for proper alignment and integration thereof. Although not separately depicted, the housing 100 may include doors, panels or other access points to allow personnel access to internal components for servicing, adjustments or replacements. The housing 100 may serve as a safety barrier, containing any potential issues such as leaks, overheating or other malfunctions that may arise during operation of the furnace 12. The housing 100 may include safety features, such as interlocks to prevent access to the interior while the furnace 12 is in operation.

The chamber 110 of the furnace 12 is where an oxidation process takes place. The chamber 110 may be or include high-purity quartz or other materials that can withstand high temperatures used for oxide growth. The material of the chamber 110 may also be chemically inert to prevent contamination of a wafer 190 on which oxide is grown. The chamber 110 may have cylindrical shape, but the shape may vary based on design of the furnace 12 and selected process. The chamber 110 may have size that is associated with wafer size (e.g., 200 millimeters or 300 millimeters) and number of wafers being processed simultaneously. The chamber 110 may have size selected to be large enough to accommodate a wafer boat and allow for uniform gas flow while not so large as to make temperature control untenable.

The heater 120 may include heating elements that are arranged around the chamber 110 to provide uniform heating. In some embodiments, the heater 120 includes resistance heaters made from materials such as silicon carbide. Thermocouples or other temperature sensors may be arranged beneficially to monitor temperature within the chamber 110. Feedback loops, which may be controlled by the controller 90, maintain the temperature in the chamber 110 at a set point, for example, by adjusting power to the heating elements.

The gas transport lines 152, 154, 156, 158 may include gas inlets that are beneficial for controlled introduction of process gases (e.g., DCS, N2O) and/or purge gases (N2) into the chamber 110. The gas transport lines 152, 154, 156, 158 may have mass flow controllers (MFCs) attached thereto, which are beneficial to regulate flow rates of the process and/or purge gases. The gas transport lines 152, 154, 156, 158 are coupled to (e.g., in fluid communication with) the gas supplies 142, 144, 146, 148, respectively. The gas supplies 142, 144, 146, 148 may include gas tanks, which may store the process and/or purge gases as liquids. The gas transport lines 152, 154, 156, 158 may be or include stainless steel or another corrosion-resistant material, and may connect the gas supplies 142, 144, 146, 148 to the chamber 110. Pressure regulators and/or valves may be included in the gas transport lines 152, 154, 156, 158 that reduce pressure from the gas supplies 142, 144, 146, 148 and/or allow operators to turn on/off flow of gases manually and/or automatically.

The stand 130 is in the chamber 110. In some embodiments, the stand 130 is operable to enter and leave the chamber 110. For example, a wafer 190 may be placed on the stand 130 outside the chamber 110, then the stand 130 may extend upward into the chamber 110 for processing (e.g., oxide growth) of the wafer 190. The stand 130 may be a wafer boat that includes a large number of stands or slots on which individual wafers may be supported during processing. The stand 130 may include a material that is resistant to corrosion, thermal stress and contamination, such as quartz, silicon carbide (SiC), other high-purity, heat-resistant ceramics or the like. The stand 130 may have a flat or slightly contoured surface to hold the wafers horizontally or vertically, which may be beneficial to achieve uniform exposure to the process gases. The stand 130 may include slots or grooves that securely hold the wafers in place without causing mechanical stress. The stand 130 may hold a few wafers or several dozen in a batch process.

The wafer 190 may be positioned on the stand 130 during processing, such as high-temperature oxide growth. The wafer 190 may be a semiconductor substrate, such as a bulk semiconductor, or the like, which may be doped (e.g., with a p-type or an n-type dopant) or undoped. The semiconductor material of the wafer 190 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

While the wafer 190 is supported by the stand 130 in the chamber 110, the heater 120 may heat the chamber 110 to a selected temperature and the process gases and optionally the purge gas may be introduced into the chamber 110 to form a thin film layer of material on the wafer 190. For example, in a nanostructure field-effect transistor (NSFET) process, an interfacial layer (IL) may be formed on silicon channels that are stacked vertically. The interfacial layer may be a silicon dioxide layer that is formed in the chamber 110 by introducing DCS and N2O gases that react according to the following relationship: SiH2Cl2+2 N2O->SiO2+2 N2+2 HCl. In one example embodiment, the DCS gas may be introduced via the gas transport line 152 and the gas transport line 156 and the N2O gas may be introduced via the gas transport line 158. A purge gas, such as N2, may be introduced via the gas transport line 154. The purge gas may be introduced in-situ, ex-situ, or both. Namely, the purge gas may be introduced during one or more of while the process gases are introduced, after the process gases are shut off but before the wafer 190 is removed, and after the wafer 190 is removed with the process gases still shut off.

In each of the in-situ and ex-situ purging operations just described, byproducts that include gases and particles may be present in the chamber 110. For example, the reaction described above forms N2, HCl and SiO2. A particulate byproduct includes silicon dioxide. When reaction conditions are not tuned properly, instead of forming a smooth thin film of SiO2 on the wafer 190, particulate or powdery SiO2 may be formed in gas phase and then be deposited on the wafer 190 or float within the chamber. These particulates are can lead to defects on the wafer 190.

An incomplete reaction during the chemical vapor deposition (CVD) process involving DCS and N2O may contribute to the formation of particulate byproducts. For example, when the reaction between DCS and N2O is incomplete, unreacted precursors or intermediates may decompose and nucleate to form particulate matter. The particulates are often small silicon-containing compounds or clusters. Incomplete reactions may be linked to process condition variation, for example, due to temperature that is too low for the reaction to complete fully, variations in precursor flow ratios or issues with mixing of reactant gases. Too high a temperature can also lead to unwanted secondary reactions or gas-phase nucleation before the precursors reach the wafer 190. For example, before the reactant gases reach the wafer 190, they may react with each other in the gas phase, such as when concentration of the process gases in the chamber 110 is too high or if chamber pressure varies outside of a selected range. This may lead to formation of particulates in the gas phase, which can then deposit onto the wafer 190 or remain in the chamber 110. An incomplete reaction can also result in the accumulation of byproducts such as HCl, which when not efficiently removed from the chamber 110, may contribute to further undesired secondary reactions.

In many CVD apparatuses, regular cleaning of the chamber may prevent particulate byproduct accumulation. For example, periodic maintenance and chamber cleaning may be beneficial to maintaining a consistent, high-quality deposition process. Monitoring quality of deposited films through spectroscopy and checking for particulates using microscopy can provide feedback to improve the deposition or growth process. However, these methods are time-consuming and are performed after a wafer has been processed.

In embodiments of the present disclosure, particulate flow through an exhaust line 170 is monitored by an optical scanner 180 to provide timely feedback about the presence of particles in the chamber 110 (or a “particle parameter”) to a controller 90. In response to the particle parameter exceeding a threshold value, the controller 90 may adjust flow of the purge gas (e.g., N2) to improve removal of the particles from the chamber 110, thereby reducing contamination of the wafer 190 and the interior of the chamber 110. Maintaining a low level of particles on inner surfaces of the chamber 110 (or “chamber particles”) is also beneficial to avoid the chamber particles being knocked loose during introduction of gases and settling on the wafer 190.

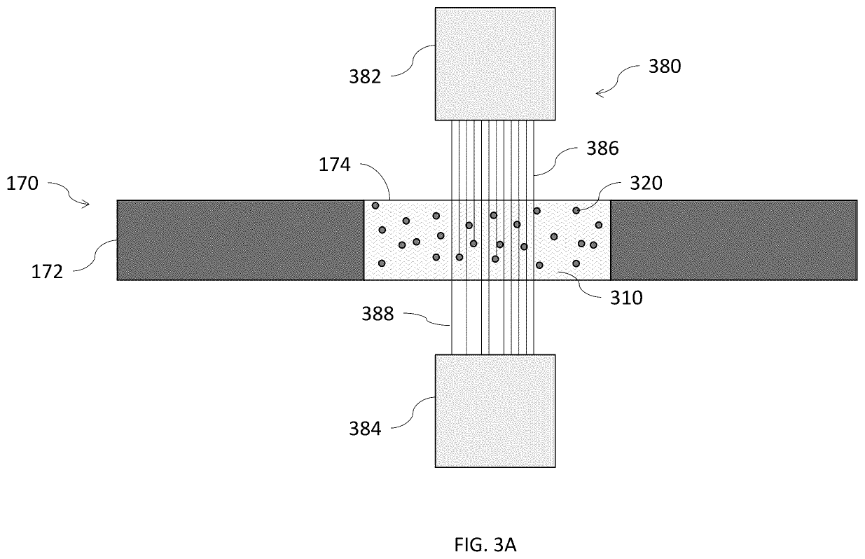

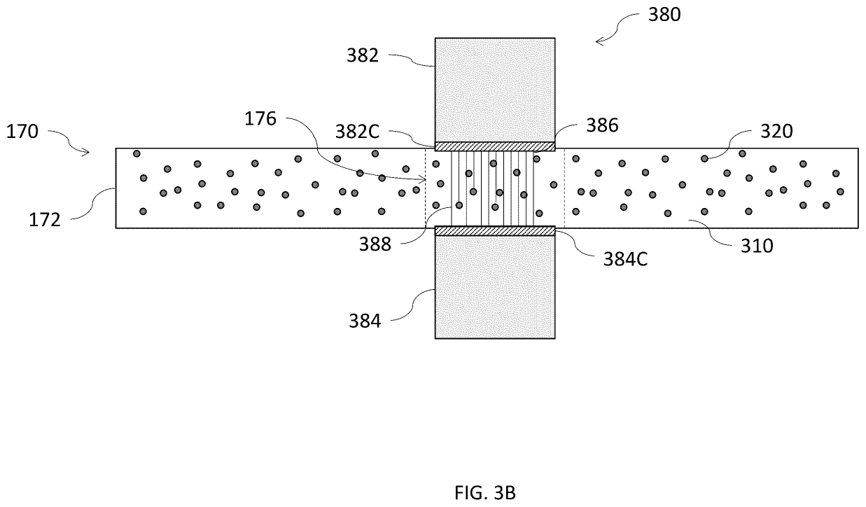

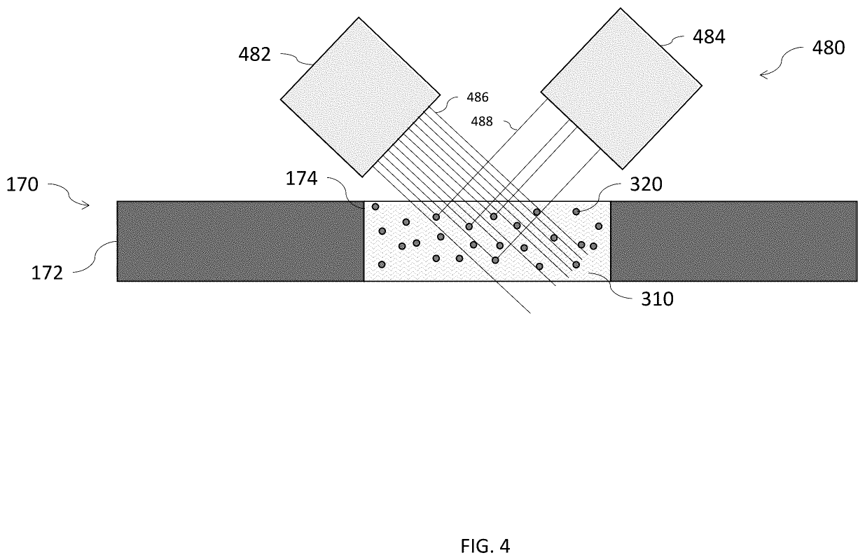

The exhaust line 170 may be connected to the chamber 110 and a pump 160. The exhaust line 170 coupled to the furnace 12 safely removes waste gases, particulate byproducts and excess reactants from the chamber 110. The exhaust line 170 may be or include a corrosion-resistant material, such as stainless steel or plastic that can handle corrosive or toxic exhaust gases. The exhaust line 170 may be a primary conduit for directing waste gases from the chamber 110 to an abatement or scrubbing system (not depicted for simplicity). The exhaust line 170 may include one or more control valves that allow for manual or automatic adjustment of flow rate within the exhaust line 170. The exhaust line 170 may include an emergency shut-off valve that can be closed quickly in an emergency to contain hazardous gases. The exhaust line 170 may include one or more filters and/or traps, such as particle filters that can capture solid particulates present in an exhaust stream and/or water and oil traps that can prevent liquids from entering a vacuum pump 160 or other sensitive components. The exhaust line 170 may include pressure sensors and controllers that monitor pressure within the exhaust line 170, providing feedback beneficial for maintaining selected pressure levels. Pressure controllers may work in conjunction with the valves and the pump 160 to maintain a selected exhaust pressure. The exhaust line 170 may be connected to an abatement or scrubbing system that can include wet scrubbers that use water or other liquids to capture contaminants or thermal abatement systems that break down hazardous compounds through combustion. The exhaust line 170 includes one or more transparent sections that allow for optical scanning of particulate flow through the exhaust line 170 by an optical scanner 180. The exhaust line 170 and optical scanner 180 are described in greater detail with reference to FIGS. 3A, 3B and 4.

The pump 160 is coupled to the exhaust line 170. The pump 160 is beneficial for controlling pressure inside the chamber 110 and efficiently removing waste gases from the chamber 110. The pump 160 may be a mechanical vacuum pump (e.g., a rotary vane pump) that can provide moderate vacuum levels. In some embodiments, the pump 160 includes a turbomolecular pump, cryogenic pump, or the like. The pump 160 may be or include materials that are compatible with the gases being handled, resistant to corrosion, and capable of withstanding operating conditions of the apparatus 10. The pump 160 may include a motor and drive system that provides mechanical power to operate the pump 160. The pump 160 may include an inlet that connects the pump 160 to the chamber 110 and/or exhaust line 170. The pump 160 may include an outlet that directs pumped gases to a next stage of an exhaust system, such as the abatement or scrubbing system. The pump 160 may include safety features (e.g., pressure relief valves, leak detection system, or the like) and monitoring and/or control systems (e.g., pressure, temperature and/or speed sensors, controllers, and the like).

The optical scanner 180 is operable to detect presence of particles in exhaust flow through the exhaust line 170. In some embodiments, the optical scanner 180 is a light scattering particle counter. For example, the optical scanner 180 may intersect a sample of air or liquid passing through the exhaust line 170 by a laser beam. Particles passing through the laser beam scatter light, which is detected by a sensor of the optical scanner 180. Intensity of the scattered light may be proportional to particle size, allowing the optical scanner 180 to size and count particles. In some embodiments, the optical scanner 180 is a condensation particle counter (CPC). For example, the particles may be enlarged by condensing a vapor onto them (e.g., water or alcohol), making the particles easier to detect. The particles are then counted, for example, by optical methods.

In some embodiments, the optical scanner 180 is or includes an aerosol spectrometer. The aerosol spectrometer may include a sample inlet, which is a point where an aerosol sample is introduced into the instrument. A charging device may electrically charge particles to improve consistent behavior in an electric field. The aerosol spectrometer may include a sizing device, which may be an optical sizing device, differential mobility analyzer (DMA) device, time-of-flight (ToF) device, or the like. In the optical sizing device, particles scatter light from a laser, and the scattered light is detected by photodetectors. The intensity and pattern of scattering can provide information about particle size. In the DMA device, particles may be sized based on electrical mobility thereof. Charged particles move in an electric field, and velocity of the particles is associated with size thereof. In the ToF device, the time it takes for particles to traverse a selected distance is measured, generating information about particle aerodynamic properties and size. In some embodiments, the optical scanner 180 includes a signal processor, which may analyze signals from detectors to generate particle size and concentration information. Additional detailed description of the optical scanner 180 is provided with reference to FIGS. 3A, 3B and 4 below.

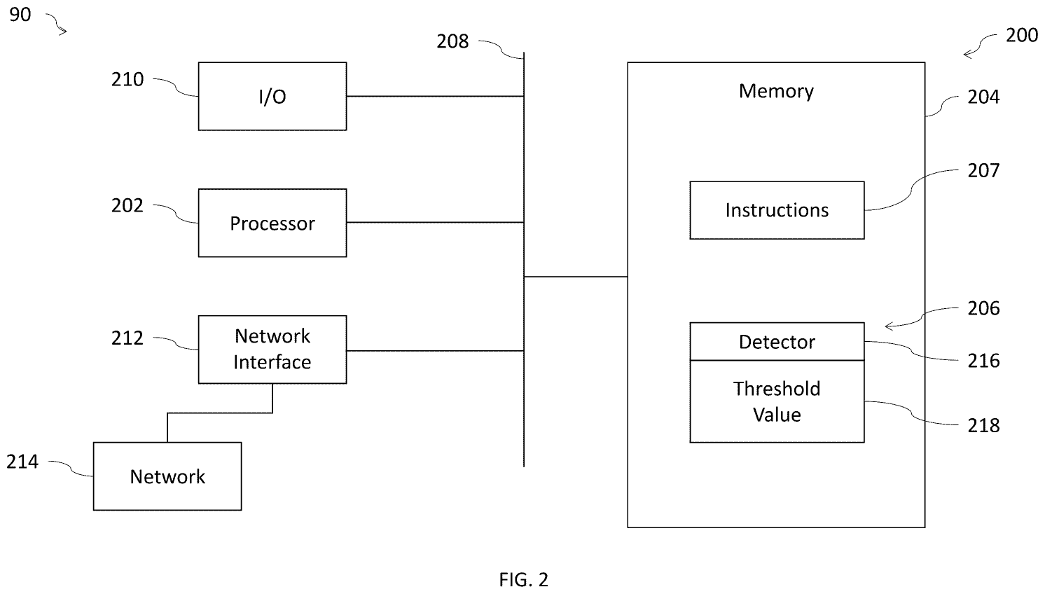

The controller 90 controls various operations of the gas supplies 142, 144, 146, 148, the heater 120, the pump 160 and the detector 180. In some embodiments, the controller 90 controls operations of the gas transport lines 152, 154, 156, 158. The controller 90 may be or include a processor, microcontroller, programmable logic controller (PLC) or other suitable integrated circuit (IC). The controller 90 may include temperature control logic, such as multi-loop control that manages several control loops for different zones in the furnace and/or proportional-integral-derivative (PID) control algorithms for maintaining precise temperature control. The controller 90 may include gas flow and pressure control, including analog inputs for reading analog signals from one or more sensors, such as flow meters and pressure sensors. The controller 90 may also include control algorithms that control valves and pumps (e.g., of the gas transport lines 152, 154, 156, 158) based on sensor readings. The controller 90 may include other circuit logic, such as safety features including emergency shut-off controls, such that, in the event of a malfunction, the controller 90 can initiate a safe shutdown procedure. The controller 90 may provide alerts for abnormal conditions such as over-temperature, under-pressure, and the like. Connectivity and communication in the controller 90 may include networking protocols for integration with other systems. Remote monitoring and control of the controller 90 can provide an ability to manage and monitor the furnace 12 remotely. The controller 90 may be operable to provide a user interface, such as a graphical interface allowing operators to monitor and control processes. The controller 90 may also include data logging circuitry for storing process data for analysis and troubleshooting. The controller 90 in accordance with various embodiments is described in detail with reference to FIG. 2.

In FIG. 2, the controller 90 includes a processor 202, a memory 200, a data interface 210 and a network interface 212. Some elements of the controller 90 may be omitted from view for simplicity of illustration. For example, the controller 90 may include a power supply (e.g., voltage regulator), analog-to-digital converters (ADCs), digital-to-analog converters (DACs), pulse width modulation (PWM) controller, clocks and timing circuitry, and the like. The controller 90 may be referred to as a control system 90.

The control system 90 generates output control signals for controlling operation of one or more components of the apparatus 10. The control system 90 may receive input signals from one or more components of the apparatus 10. In some embodiments, the control system 90 is located adjacent the apparatus 10, remote from the apparatus 10 or in the apparatus 10.

Control system 90 includes a processor 202 and a non-transitory, computer readable storage medium 204 encoded with, i.e., storing, computer program code 206, i.e., a set of executable instructions. Computer readable storage medium 204 is also encoded with instructions 207 for interfacing with components of apparatus 10. The processor 202 is electrically coupled to the computer readable storage medium 204 via a bus 208. The processor 202 is also electrically coupled to an I/O interface 210 by bus 208. A network interface 212 is also electrically connected to the processor 202 via bus 208. Network interface 212 is connected to a network 214, so that processor 202 and computer readable storage medium 204 are capable of connecting to external elements via network 214. The processor 202 is configured to execute the computer program code 206 encoded in the computer readable storage medium 204 in order to cause control system 90 to be usable for performing a portion or all of the operations as described with respect to apparatus 10, including those that will be described with reference to FIGS. 3A-6 below.

In some embodiments, the processor 202 is a central processing unit (CPU), a multi-processor, a distributed processing system, an application specific integrated circuit (ASIC), and/or a suitable processing unit.

In some embodiments, the computer readable storage medium 204 is an electronic, magnetic, optical, electromagnetic, infrared, and/or a semiconductor system (or apparatus or device). For example, the computer readable storage medium 204 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 204 includes a compact disk-read only memory (CD-ROM), a compact disk-read/write (CD-R/W), and/or a digital video disc (DVD).

In some embodiments, the storage medium 204 stores the computer program code 206 configured to cause control system 90 to perform the operations as described with respect to apparatus 10. In some embodiments, the storage medium 204 also stores information needed for performing the operations as described with respect to apparatus 10, such as a particle parameter 216, a threshold value parameter 218, and/or a set of executable instructions to perform the operations as described with respect to apparatus 10.

In some embodiments, the storage medium 204 stores instructions 207 for interfacing with apparatus 10 (e.g., heater 120, gas transport lines 152, 154, 156, 158 and the like). The instructions 207 enable processor 202 to generate operating instructions readable by elements of the apparatus 10 to effectively implement the operations as described with respect to apparatus 10.

Control system 90 includes I/O interface 210. I/O interface 210 is coupled to external circuitry. In some embodiments, I/O interface 210 includes a keyboard, keypad, mouse, trackball, trackpad, and/or cursor direction keys for communicating information and commands to processor 202.

Control system 90 also includes network interface 212 coupled to the processor 202. Network interface 212 allows control system 90 to communicate with network 214, to which one or more other computer systems are connected. Network interface 212 includes wireless network interfaces such as BLUETOOTH, WIFI, WIMAX, GPRS, or WCDMA; or wired network interface such as ETHERNET, USB, or IEEE-1394.

Control system 90 is configured to receive information related to the optical scanner, e.g., optical scanner 180 (FIGS. 1A, 1B, 3 and 4), through I/O interface 210. The information is transferred to processor 202 via bus 208 and then stored in computer readable medium 204 as particle parameter 216. Control system 90 is configured to receive information related to the threshold value through I/O interface 210. In some embodiments, the threshold value is received from an operator. The information is stored in computer readable medium 204 as threshold value parameter 218.

During operation, in some embodiments, processor 202 executes a set of instructions to determine whether the particle parameter has exceeds a threshold value. Based on the above determinations, processor 202 generates a control signal to instruct one or more of the gas supplies 142, 144, 146, 148, the gas transport lines 152, 154, 156, 158 and the pump 160 to adjust flow of a purge gas (e.g., N2) and/or flow of exhaust in the exhaust line 170. In some embodiments, the control signal is transmitted using I/O interface 210. In some embodiments, the control signal is transmitted using network interface 212.

FIGS. 3A, 3B and 4 are diagrammatic views of optical scanners 380, 480 in accordance with various embodiments. The optical scanners 380, 480 are embodiments of the optical scanner 180 of FIGS. 1A and 1B. The optical scanner 380 of FIGS. 3A, 3B is a forward light scattering optical scanner 380. The optical scanner 480 of FIG. 4 is a side (or 90-degree) light scattering optical scanner 480. It should be understood that the optical scanners 380, 480 are examples, and the apparatus 10 may include another appropriate optical scanner in some embodiments.

In FIG. 3A, the optical scanner 380 includes a light source 382 and a detector 384 arranged on opposite sides of an optically transparent section 174 of the exhaust line 170. The transparent section 174 may be between opaque sections 172 of the exhaust line 170. For example, the transparent section 174 may be or include glass or plastic that has high transparency, such as transparency that exceeds about 95%. The opaque sections 172 may be stainless steel or another material that is resistant to corrosion.

The optical scanner 380 is operable to generate the particle parameter 216, which may include one or more of a count of particles, a size of particles, a density of particles, and the like. The light source 382 is operable to generate light 386, which may include one or more laser beams. The light 386 is directed toward the detector 384. Some of the light 386 is scattered (e.g., blocked or deflected) by particles 320 in an exhaust medium 310 (e.g., gas byproducts and particulate byproducts) passing through the transparent section 174. As such, intensity of light 388 that is incident on the detector 384 is less than that of the light 386 generated by the light source 382.

The light source 382 may be a laser source that provides a coherent light beam 386 that interacts with particles in the sample. In some embodiments, the laser includes a He—Ne (Helium-Neon) or diode laser. The detector 384 may include a photodetector that converts the scattered light 388 into an electrical signal. The intensity of the light 388 that is not scattered (and thus amplitude of the electrical signal) is associated with the particle size.

The optical scanner 380 may include a signal processor that analyzes the electrical signals from the photodetector. The signal processor may distinguish between noise and actual particle events and may size the particles 320 based on the intensity of the scattered light 388. The optical scanner 380 may include a counting circuit that tracks number of particles 320 detected. The counting circuit may associate particles with different size bins. The optical scanner may include a data storage for storing data and/or for transferring the data to external devices (e.g., the controller 90) for further analysis or record-keeping.

In FIG. 3A, the light source 382 and the detector 384 are arranged adjacent to the transparent section 174 but outside the exhaust line 170. Namely, the laser(s) and the photodetectors are not exposed to the exhaust medium 310, which may be corrosive and could damage the laser(s) or photodetectors. The transparent section 174 may introduce refraction that complicates calculation of particle sizes and numbers associated with variations in intensity of the light 388.

In FIG. 3B, the light source 382 and the detector 384 are arranged to be flush with a wall of the exhaust line 170 or slightly inside the exhaust line 170 in a first section 176 of the exhaust line 170, as shown. The light source 382 may include a transparent protective cover or cap 382C that is between internal elements (e.g., lasers) of the light source 382 and the interior of the exhaust line 170. The detector 384 may include a transparent protective cover or cap 384C that is between internal elements (e.g., photodetectors) of the detector 384 and the interior of the exhaust line 170. The protective caps 382C, 384C may be or include an appropriate material that is transparent and resistant to corrosion. In some embodiments, the protective caps 382C, 384C include a glass, plastic, or the like.

In FIG. 4, the optical scanner 480 is a side (or 90-degree) light scattering optical scanner 480. As depicted in FIG. 4, the optical scanner 480 may include a light source 482 and a detector 484 arranged on the same side of the optically transparent section 174 of the exhaust line 170. The light source 482 and the detector 484 are similar in most respects to the light source 382 and the detector 384, respectively, described with reference to FIG. 3A. In the side light scattering optical scanner 480, the light source 482 generates light 486 that is incident on the exhaust medium 310, and the detector 484 detects scattered light 488.

In the optical scanner 480, the detector 484 is positioned perpendicular to the direction of the laser beam 486, capturing light 488 scattered at a 90-degree angle. This configuration can be more sensitive to smaller particles 320 and may be beneficial to providing a good balance between sensitivity and dynamic range.

The optical scanner 480 may be arranged similarly to the optical scanner 380 depicted in FIG. 3B in some embodiments. Namely, instead of being outside the exhaust line 170, the light source 482 and the detector 484 may each be positioned to be flush with or slightly inside the interior of the exhaust line 170.

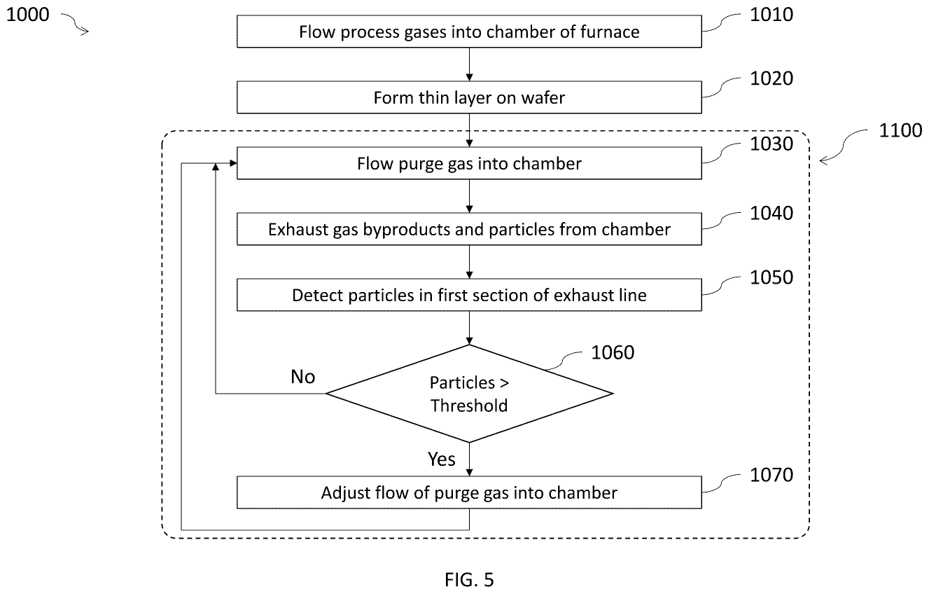

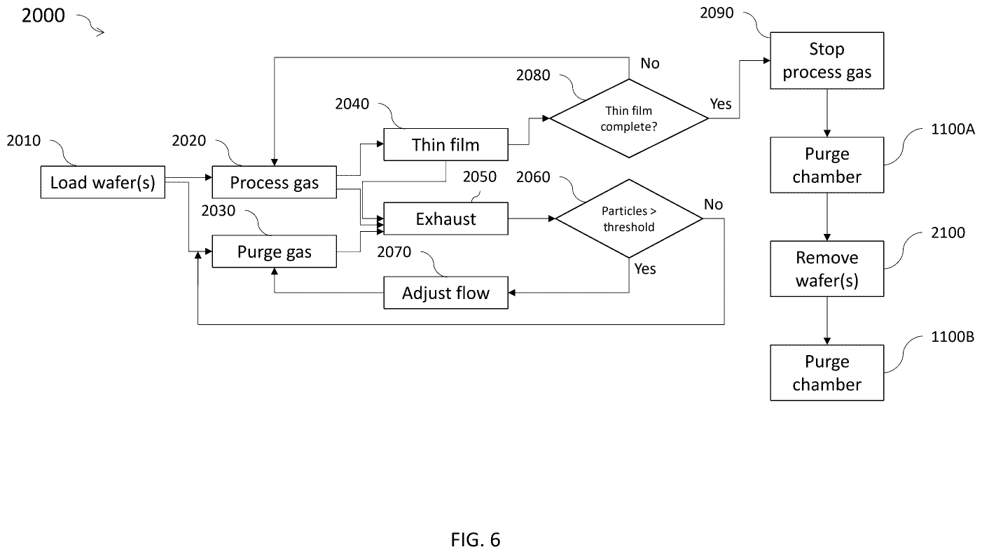

FIGS. 5 and 6 are flowcharts illustrating methods 1000, 2000 of processing a semiconductor device according to various aspects of the present disclosure. The acts illustrated in FIGS. 5 and 6 may be performed in accordance with the apparatus 10 described with reference to FIGS. 1A-4. FIGS. 5 and 6 illustrate flowcharts of methods 1000, 2000 for processing a semiconductor device, according to one or more aspects of the present disclosure. Methods 1000, 2000 are examples and are not intended to limit the present disclosure to what is explicitly illustrated in methods 1000, 2000. Additional acts can be provided before, during and after the methods 1000, 2000 and some acts described can be replaced, eliminated, or moved around for additional embodiments of the methods. For example, the methods 1000, 2000 may be used for forming thin films on a plurality of wafers arranged on a wafer boat. Not all acts are described herein in detail for reasons of simplicity. For example, acts for loading and/or removing a wafer are not described in the method 1000, but may be performed as part of the method 1000. Similarly, acts that follow the acts of methods 1000, 2000, for example, that are related to singulation and packaging of IC dies are also omitted from view and not described in detail herein. Acts of methods 1000, 2000 are described below with reference to elements of the apparatus 10 of FIGS. 1A-4. Many of the acts may be performed by the controller 90. For example, the controller 90 may execute instructions to perform the acts of methods 1000, 2000. It should be understood that the methods 1000, 2000 are not limited to being performed by the apparatus 10 and/or the controller 90, and may be performed by systems that differ in one or more respects from the apparatus 10 and/or controller 90 in other embodiments.

In FIG. 5, the method 1000 begins with act 1010, which includes flowing process gases into a chamber of a furnace. For example, the process gases (e.g., DCS and N2O) may be flowed into the chamber 110 of the furnace 12 via the gas transport lines 152, 156, 158, as described with reference to FIGS. 1A and 1B.

Act 1020 follows act 1010. With a wafer in place in the chamber, a thin layer of material (e.g., silicon dioxide) is formed on the wafer. In act 1020, the wafer may be heated by a heater (e.g., the heater 120) of the furnace. The wafer may be heated to a high temperature suitable for forming high-temperature oxide. For example, the temperature may be in a range of about 800 degrees Celsius to about 1200 degrees Celsius. The wafer may be the wafer 190 and may include a semiconductor device. The semiconductor device may be any semiconductor device, such as, but not limited to, a logic device, a memory device or any other semiconductor device. The semiconductor device generally includes a semiconductor device layer, a frontside interconnection structure, an optional backside interconnection structure and one or more electrical contacts. In most embodiments, the wafer is a semiconductor wafer that has multiple integrated circuit (IC) chips or dies formed therein. The semiconductor device layer may include a semiconductor substrate, which may be referred to as the substrate. The substrate may be any suitable substrate. In some embodiments, the substrate may be a semiconductor wafer. In some embodiments, the substrate may be a monocrystalline silicon (Si) wafer, an amorphous Si wafer, a gallium arsenide (GaAs) wafer, or any other semiconductor wafer.

The semiconductor device layer includes one or more semiconductor devices. The semiconductor devices included within the semiconductor device layer may be any semiconductor devices in various embodiments. In some embodiments, the semiconductor device layer includes one or more transistors, which may include any suitable transistor structures, including, for example, planar transistors, fin-type transistors (FinFETs), or nanostructure transistors, such as gate-all-around (GAA) transistors, or the like. In some embodiments, the semiconductor device layer includes one or more GAA transistors. In some embodiments, the semiconductor device layer may be a logic layer that includes one or more semiconductor devices, and may further include their interconnection structures, that are configured and arranged to provide a logical function, such as AND, OR, XOR, XNOR, or NOT, or a storage function, such as a flipflop or a latch. In some embodiments, the semiconductor device layer may include a memory device, which may be any suitable memory device, such as, for example, a static random access memory (SRAM) device. The memory device may include a plurality of memory cells that are constructed in rows and columns, although other embodiments are not limited to this arrangement. Each memory cell may include multiple transistors (e.g., six) connected between a first voltage source (e.g., VDD) and a second voltage source (e.g., VSS or ground) such that one of two storage nodes can be occupied by the information to be stored, with the complementary information stored at the other storage node. The semiconductor device layer of the device may further include various circuitry that is electrically coupled to the semiconductor device layer. For example, the semiconductor device layer may include power management or other circuitry that is electrically coupled to the one or more semiconductor devices of the semiconductor device layer. The power management circuitry may include any suitable circuitry for controlling or otherwise managing communication signals, such as input power signals, to or from the semiconductor devices of the semiconductor device layer. In some embodiments, the power management circuitry may include power-gating circuitry which may reduce power consumption, for example, by shutting off the current to blocks of the circuit (e.g., blocks or electrical features in the semiconductor device layer) that are not in use, thereby reducing stand-by or leakage power. In some embodiments, the semiconductor device layer includes one or more switching devices, such as a plurality of transistors, that are used to transmit or receive electrical signals to and from the semiconductor devices in the semiconductor device layer, such as to turn on and turn off the circuitry (e.g., transistors, etc.) of the semiconductor device layer.

The forming a thin layer of act 1020 may include forming a silicon dioxide interfacial layer on channels of a GAAFET, as described with reference to FIGS. 1A and 1B. In some embodiments, the forming a thin layer includes forming an oxide layer in a process such as a sacrificial gate dielectric in a sacrificial gate structure, a dielectric layer in a shallow trench isolation (STI), or the like.

Acts 1030, 1040, 1050, 1060 and 1070 may be referred to collectively as a purge process 1100. The purge process 1100 is depicted as following the thin layer formation act 1020 in FIG. 5. In some embodiments, such as in the method 2000 of FIG. 6, the purge process 1100 may be performed in-situ (e.g., during formation of the thin layer) and/or ex-situ, such as after completion of the thin layer before removing the wafer from the chamber, after removing the wafer from the chamber, or both.

Act 1030 follows act 1020. During or following formation of the thin layer in act 1020, a purge gas is flowed into the chamber in act 1030. For example, the purge gas (e.g., N2) may be flowed into the chamber 110 via the gas transport line 154, as described with reference to FIGS. 1A and 1B. The purge gas may initially be flowed at a first rate or “first flow rate” in act 1030. Based on a result of performing acts 1040-1070, the purge gas may be flowed at a second rate different from the first rate in act 1030. The second rate may be greater than the first rate. In some embodiments, the purge gas is flowed via an adjusted profile that may include a low rate punctuated by periods of a higher rate.

Act 1040 follows act 1030. In act 1040, following introduction of the purge gas into the chamber, gas byproducts and particles are exhausted from the chamber. For example, the pump 160 may generate suction that pulls gas byproducts and particulate byproducts (e.g., the exhaust medium 310 including particles 320) out of the chamber 110 through the exhaust line 170. The exhaust line 170 may be any of the exhaust lines 170 described with reference to FIGS. 3A, 3B and 4.

Act 1050 follows act 1040 and may be performed simultaneously with act 1040. In act 1050, while the particles are being exhausted, the particles are detected in a first section of the exhaust line. For example, the particles 320 may be detected by the optical scanner 180, 380, 480 that is adjacent and/or inside the exhaust line 170. The first section may be the transparent section 174 or the first section 176. Detection of the particles may be via detecting intensity of light exiting the first section that is not scattered, in some embodiments, such as described with reference to FIGS. 3A and 3B. The detection may be via detecting intensity of scattered light via a detector arranged at a 90-degree angle to the direction of light generated by a light source, such as described with reference to FIG. 4. In act 1050, the detection may include detecting number of the particles. For example, a count of the particles associated with an interval of time or “particle flow rate” may be generated by the detector. In another example, a density of the particles relative to volume of the exhaust line exposed to the light may be detected. A result of the detection as just described may be referred to as a “particle parameter,” which may be an embodiment of the particle parameter 216 of FIG. 2.

The detection may include detecting size of the particles. In some embodiments, particles outside of a selected size range may be disregarded or omitted from the detection. For example, particles having size that does not exceed about 200 nanometers may be omitted from a count or density measurement generated by the detector.

Act 1060 follows act 1050. Following generating the particle parameter in act 1050, a determination may me made whether the particle parameter exceeds a threshold value (e.g., the threshold value 218 of FIG. 2). The threshold value may correspond to the particle parameter. For example, the particle parameter may be a count of particles and the threshold value may be a number of particles. A comparison may be made between the count of particles that pass through the first section of the exhaust line (e.g., over a period of time) and the threshold value. In another example, the particle parameter may be a density of particles and the threshold value may be a density value.

In response to the particle parameter not exceeding the threshold value, the method 1000 may return to act 1030 to flow the purge gas into the chamber, e.g., at the first rate that is not adjusted due to the level of particles in the exhaust not being sufficiently high to warrant adjusting the rate of flow of the purge gas.

In response to the particle parameter exceeding the threshold value, the method 1000 may proceed to act 1070. In act 1070, which follows act 1060, flow of the purge gas into the chamber is adjusted. For example, flow of the purge gas (e.g., N2) into the chamber 110 may be adjusted by the controller 90. The flow of the purge gas may be increased. Increasing the flow may be beneficial to exhaust more of the particles out of the chamber 110 more quickly before the particles can settle on the wafer or the interior surface(s) of the chamber 110. Increasing the flow may also be beneficial to dislodge and exhaust particles from the wafer surface and/or the interior surface(s) of the chamber. In some embodiments, increasing the flow of the purge gas may include increasing the flow of the purge gas by more than about 10%, more than about 20%, more than about 50%, more than about 100% or another suitable amount which may be between 10% and 100% or may exceed 100%.

In some embodiments, in act 1070, adjusting the flow of the purge gas includes adjusting the flow according to a flow profile that has dynamic or variable levels of flow rate over time. For example, the flow profile may include a first flow rate punctuated by intervals at a second flow rate that exceeds the first flow rate (e.g., is 10%, 20%, 50%, 100% or more greater than the first flow rate). Namely, instead of a constant flow at a higher flow rate, the purge gas may be flowed with a variable flow, such as a chain of pulses at a higher flow rate separated by intervals at a lower flow rate. Use of a flow profile with variable flow rates may be beneficial to dislodge particles from the wafer surface and/or the interior surface(s) of the chamber.

Following adjusting the flow of the purge gas in act 1070, the method 1000 may return to act 1030, in which the adjust flow of the purge gas may be used when flowing purge gas into the chamber.

Additional acts may follow act 1070. For example, the wafer may be removed from the chamber following completion of the thin layer. The wafer may be cooled, for example, to room temperature. Inspection of the thin layer may be performed. Then, additional operations to pattern the thin layer and/or form other layers on the thin layer may be performed.

By adjusting the purge gas dynamically in response to level of particles in the exhaust line, the method 1000 may reduce particles that settle on the wafer, which may improve yield.

FIG. 6 is a flowchart of method 2000 in accordance with various embodiments. Some acts may be omitted from view in FIG. 6. For example, an act of detecting particles in an exhaust line is omitted from view in FIG. 6.

In FIG. 6, the method 2000 begins with act 2010, which includes loading a wafer into a chamber of a furnace of a CVD apparatus, such as the apparatus 10. For example, the wafer 190 may be loaded into the chamber 110 by the wafer stage 130.

Acts 2020 and 2030 follow act 2010 and may be performed simultaneously. In act 2020, following loading the wafer into the chamber, process gas(es) is flowed into the chamber. Act 2020 is the same as or similar in most respects to act 1010 of method 1000 of FIG. 5. For example, DCS and N2O may be flowed into the chamber 110 as described with reference to FIGS. 1A and 1B.

Act 2030 is performed simultaneously with act 2020. In act 2030, following loading the wafer into the chamber, a purge gas is flowed into the chamber. Act 2030 is the same as or similar in most respects to act 1030 of method 1000 of FIG. 5. For example, the purge gas (e.g., N2) is flowed into the chamber as described with reference to FIGS. 1A and 1B.

Act 2040 follows and is performed during acts 2020 and 2030. In act 2040, while the process gas(es) and purge gas are flowed into the chamber, a thin film is formed. Act 2040 may be the same as or similar in most respects to act 1020 of method 1000 of FIG. 5. For example, the thin film may be a silicon dioxide thin film formed on the wafer 190, e.g., as an interfacial layer of an active gate structure that wraps around silicon nanosheet channels of a GAAFET.

Act 2050 follows and is performed simultaneously with acts 2020, 2030 and 2040. In act 2050, during flowing of the process gas(es) and the purge gas and formation of the thin film on the wafer, byproducts of acts 2020, 2030 and 2040 are exhausted from the chamber. Act 2050 may be the same as or similar in most respects to act 1040. For example, the purge gas (e.g., N2) in coordination with the pump 160 may draw gas byproducts (e.g., HCl and N2) and particulate byproducts (e.g., SiO2) from the chamber 110 via the exhaust line 170.

Act 2060 follows and may be performed during act 2050. As the byproducts of acts 2020, 2030 and 2040 are exhausted from the chamber, a determination is made whether a particle parameter exceeds a threshold value. The particle parameter of act 2060 may be the same as or similar to that described with reference to FIGS. 1A-2 and 5, such as is generated in act 1050 of the method 1000. Act 2060 may be the same as or similar in most respects to act 1060 of FIG. 5.

In response to the particle parameter not exceeding the threshold value, the method 2000 may proceed from act 2060 to act 2030, in which the purge gas is flowed at a rate that is not adjusted based on the particle parameter.

In response to the particle parameter exceeding the threshold value, the method 2000 may proceed from act 2060 to act 2070. In act 2070, flow of the purge gas is adjusted, which may be the same as or similar in most respects to act 1070 of method 1000 of FIG. 5. For example, the flow of the purge gas may be increased to improve removal of particles from the chamber 110.

Act 2070 follows and is performed during act 2040. In act 2070, a determination is made whether deposition of the thin film is completed. In some embodiments, the determination is made based on in-situ or “in-line” metrology monitoring of thickness of the thin film. In some embodiments, the determination is made based on the deposition of the thin film having proceeded for a selected interval of time. For example, deposition of the thin film may be timed via a recipe.

In response to the thin film not being complete, the method 2000 may return to act 2020 in which process gas(es) continues to be introduced into the chamber so that thickness of the thin film may be increased.

In response to the thin film being complete, the method 2000 may proceed to act 2090.

Act 2090 follows act 2080. Following completion of deposition of the thin film, flow of the process gas(es) into the chamber may be stopped. For example, the gas transport lines 152, 156, 158 that transport the process gas(es) may be closed via respective valves and the gas transport line 154 that transports the purge gas may optionally be closed. In some embodiments, the purge gas continues to flow following the thin film deposition being complete.

Purge process 1100A follows act 2090. Following completion of the thin film and stopping of the process gas(es), the purge process 1100A is performed to remove particles from the wafer surface and/or the interior surfaces of the chamber. The purge process 1100A is the same or similar in most respects to the purge process 1100 described in detail with reference to FIG. 5. The purge process 1100A immediately following act 2090 may be performed with the wafer in place in the chamber.

Act 2100 follows the purge process 1100A. In act 2100, the wafer(s) is removed from the chamber. For example, a wafer boat that holds the wafer and optionally holds additional wafers therein may be removed from the chamber.

Purge process 1100B follows act 2100. The purge process 1100B is the same as or similar to the purge process 1100 described with reference to FIG. 5. Following removal of the wafer(s), the purge process 1100B is performed to remove particles from the interior surfaces of the chamber.

Embodiments may provide advantages. The optical scanner 180, 380, 480 detects level of particles in the exhaust line. Based on the level of particles, flow of the purge gas may be adjusted to improve evacuation of the particles from the chamber 110, which can improve yield.

In accordance with at least one embodiment, a method includes: flowing a process gas into a chamber of a furnace; forming a material layer on a wafer via the process gas; flowing a purge gas into the chamber; exhausting the purge gas and particles from the chamber via an exhaust line; detecting the particles in the exhaust line; determining whether a particle parameter associated with the particles exceeds a threshold value; and in response to the particle parameter exceeding the threshold value, adjusting flow of the purge gas into the chamber.

In accordance with at least one embodiment, a method includes: loading a wafer into a chamber of a furnace; flowing process gases into the chamber; during the flowing, flowing a purge gas into the chamber; during the flowing process gases and the flowing a purge gas, forming a material layer on the wafer via the process gases; during the forming, exhausting particles from the chamber via an exhaust line; detecting the particles via an optical scanner; and in response to a particle parameter associated with the particles exceeding a threshold value, adjusting flow of the purge gas.

In accordance with at least one embodiment, a system includes: a chamber; a heater adjacent the chamber; at least two process gas inlets in communication with the chamber; at least one purge gas inlet in communication with the chamber; an exhaust line in communication with the chamber; an optical scanner positioned adjacent the exhaust line; and a controller. In operation, the controller executes instructions to: flow processes gases into the chamber; exhaust particles from the chamber; detect a particle parameter via the optical scanner; compare the particle parameter with a threshold value; and in response to the particle parameter exceeding the threshold value, adjust flow of a purge gas through the at least one purge gas inlet.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
flowing a process gas into a chamber of a furnace;
forming a material layer on a wafer via the process gas;
flowing a purge gas into the chamber;
exhausting the purge gas and particles from the chamber via an exhaust line;
detecting the particles in the exhaust line;
determining whether a particle parameter associated with the particles exceeds a threshold value; and
in response to the particle parameter exceeding the threshold value, adjusting flow of the purge gas into the chamber.

2. The method of claim 1, wherein the detecting includes detecting the particles via an optical scanner.

3. The method of claim 2, wherein the detecting includes detecting the particles via a light scattering particle counter.

4. The method of claim 3, wherein the detecting includes detecting the particles via a condensation particle counter that includes the light scattering particle counter.

5. The method of claim 3, wherein the detecting includes detecting the particles via a side light scattering particle counter having a laser emitter and a detector that are arranged on a same side of the exhaust line.

6. The method of claim 3, wherein the detecting includes detecting the particles via the light scattering particle counter that is arranged adjacent an optically transparent section of the exhaust line.

7. The method of claim 1, wherein the adjusting flow of the purge gas includes increasing the flow of the purge gas.

8. The method of claim 1, wherein:
the flowing a process gas includes flowing dichlorosilane (DCS) gas and nitrous oxide (N2O) gas;
the flowing a purge gas includes flowing nitrogen (N2) gas; and
the adjusting flow includes increasing the flow of the N2 gas.

9. A method comprising:
loading a wafer into a chamber of a furnace;
flowing process gases into the chamber;
during the flowing, flowing a purge gas into the chamber;
during the flowing process gases and the flowing a purge gas, forming a material layer on the wafer via the process gases;
during the forming, exhausting particles from the chamber via an exhaust line;
detecting the particles via an optical scanner; and
in response to a particle parameter associated with the particles exceeding a threshold value, adjusting flow of the purge gas.

10. The method of claim 9, further comprising:
determining whether the forming a material layer is complete; and
in response to the forming a material layer being complete, purging the chamber, including:
with the wafer in the chamber, detecting post-processing particles via the optical scanner; and
adjusting flow of the purge gas based on the post-processing particles detected.

11. The method of claim 10, further comprising, after the purging the chamber:
removing the wafer from the chamber;
with the wafer not present in the chamber, detecting chamber particles via the optical scanner; and
adjusting flow of the purge gas based on the chamber particles detected.

12. The method of claim 9, wherein the adjusting flow of the purge gas includes:
in response to a number of the particles exceeding a threshold value, increasing the flow of the purge gas.

13. The method of claim 9, wherein the adjusting flow of the purge gas includes:
in response to a density of the particles exceeding a threshold value, increasing the flow of the purge gas.

14. The method of claim 9, wherein the adjusting flow of the purge gas includes increasing flow of the purge gas by at least about 10%.

15. A system, comprising:
a chamber;
a heater adjacent the chamber;
at least two process gas inlets in communication with the chamber;
at least one purge gas inlet in communication with the chamber;
an exhaust line in communication with the chamber;
an optical scanner positioned adjacent the exhaust line; and
a controller that, in operation, executes instructions to:
flow processes gases into the chamber;
exhaust particles from the chamber;
detect a particle parameter via the optical scanner;
compare the particle parameter with a threshold value; and
in response to the particle parameter exceeding the threshold value, adjust flow of a purge gas through the at least one purge gas inlet.

16. The system of claim 15, wherein the controller, in operation, executes the instructions to adjust the flow of the purge gas by increasing the flow of the purge gas.

17. The system of claim 15, wherein the exhaust line includes an optically transparent section and the optical scanner is positioned adjacent the optically transparent section.

18. The system of claim 15, wherein a thin film is formed on a wafer in the chamber by the process gases, and the controller, in operation, executes the instructions to detect the particle parameter during formation the thin film.

19. The system of claim 18, wherein the controller, in operation, further executes the instructions to:
with the wafer having the thin film thereon present in the chamber, purge post-processing particles from the chamber;
detect the particle parameter associated with the post-processing particles; and
in response to the particle parameter associated with the post-processing particles exceeding the threshold value, increase flow of the purge gas into the chamber.

20. The system of claim 18, wherein the controller, in operation, further executes the instructions to:
with the wafer having the thin film thereon removed in the chamber, purge chamber particles from the chamber;
detect the particle parameter associated with the chamber particles; and
in response to the particle parameter associated with the chamber particles exceeding the threshold value, increase flow of the purge gas into the chamber.
